(19) United States
(12) Patent Application Publication
(10) Pub. No.: US 2009/0235977 A1
(43) Pub. Date: Sep. 24, 2009

(54) Key module with energy storage function

(76) Inventors: Hsin-Chin Lee, Jhongli City (TW); Hsien-Kuo Kao, Taipei City (TW); Chio-Lien Yeh, Danshuei Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/076,458

(22) Filed: Mar. 19, 2008

(51) Int. Cl. H01L 31/04

(52) U.S. Cl. 136/252

(57) ABSTRACT

A key module with energy storage function includes a transparent key unit, a sun cell, and an elastic unit. The transparent key unit has a plurality of transparent microstructures. The sun cell is disposed under a bottom side of the transparent key unit, and the sun cell has a light-receiving face facing the transparent key unit. The elastic unit is disposed under a bottom side of the sun cell. Therefore, the transparent microstructures of the transparent key unit guide and transmit external light sources onto the light-receiving face of the sun cell in order to increase light source on the light-receiving face.

### BACKGROUND OF THE INVENTION

1. Field of the Invention

The present invention relates to a key module, and particularly relates to a key module with energy storage function.

2. Description of the Related Art

With the coming age of information technology and the advance of network technologies, mobile phones (or cell phones) become one of the most widespread communication tools. Cell phones become increasingly popular for consumers due to their attribute of small in sizes, portability, versatile in functions, and most importantly, the steadily decreasing price. In terms of purchasing cell phones, the appearances and functions are the determining factors for majority buyers. Hence, the market responds to this trend by providing multi-functional, new and good-looking cell phones.

Moreover, the usage time and the standby time of the cell phone need to be increased according to user's requirement. Hence, it is important for cell phone designer to increases battery capacity and power supply efficiency, and decrease power consumption. In addition, it is a main development and research direction how to utilize and combine natural resources into electronic product.

### SUMMARY OF THE INVENTION

One particular aspect of the present invention is to provide a key module with energy storage function. The key module has a sun cell and a plurality of transparent microstructures mated with each other in order to increase light source received by the sun cell, and the power supply of sun cell can be increased. Hence, the present invention has a background showing function, a pressing function, and a power-storing function.

In order to achieve the above-mentioned aspects, the present invention provides a key module with energy storage function, including: a transparent key unit, a sun cell, and an elastic unit. The transparent key unit has a plurality of transparent microstructures. The sun cell is disposed under a bottom side of the transparent key unit, and the sun cell has a light-receiving face facing the transparent key unit. The elastic unit is disposed under a bottom side of the sun cell. Therefore, the transparent microstructures of the transparent key unit guide and transmit external light sources onto the light-receiving face of the sun cell in order to increase light source on the light-receiving face.

In order to achieve the above-mentioned aspects, the present invention provides a key module with energy storage function, including: a transparent key unit, a sun cell, a plurality of transparent microstructures, and an elastic unit. The sun cell is disposed under a bottom side of the transparent key unit, and the sun cell has a light-receiving face facing the transparent key unit. The transparent microstructures are disposed between the transparent key unit and the sun cell. The elastic unit is disposed under a bottom side of the sun cell. Therefore, the transparent microstructures guide and transmit external light sources onto the light-receiving face of the sun cell in order to increase light source on the light-receiving face.

Furthermore, the present invention further includes an adhesive layer an anti-IR (infrared) coating layer unit. The adhesive layer is disposed between the transparent key unit and the sun cell. The anti-IR coating layer unit is disposed on a top surface of the sun cell, and the anti-IR coating layer unit can be an anti-IR coating layer or can be composed of a plurality of anti-IR coating layers.

Hence, the key module with energy storage function of the present invention has some advantages, as follows:

1. The background showing function (such as shown words), the pressing function and the power-storing function are all in the same key module.

2. The sun cell is applied to the key module in order to increase the usage time and the standby time of an electronic product using the key module.

3. The transparent microstructures are used to increase the light-receiving efficiency of the sun cell.

4. The traditional rechargeable battery is replaced with the sun cell in order to take the environment and the convenience into account.

5. The present invention takes the environment and the convenience into account without using battery charger.

6. The anti-IR coating layer is used to decrease the sunshine temperature of the key module in the daytime and protect the relevant electronic components of the key module.

7. The adhesive layer is used to fix the transparent key unit on the sun cell in order to decrease reflection or total reflection of the external light sources and increase the light-receiving efficiency of the sun cell.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a side, schematic view of a key module with energy storage function according to the first embodiment of the present invention;

FIG. 2 is a side, schematic view of a sun cell of the present invention;

FIG. 3 is a side, schematic view of a key module with energy storage function according to the second embodiment of the present invention;

FIG. 4 is a side, schematic view of a key module with energy storage function according to the third embodiment of the present invention; and

FIG. 5 is a side, schematic view of another transparent microstructures of the present invention.

### DETAILED DESCRIPTION OF THE PREFERRED EMBODIMENTS

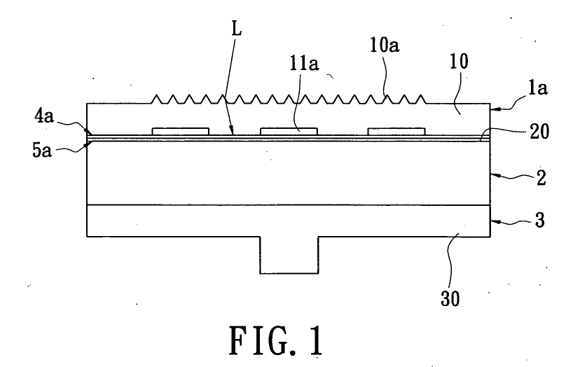

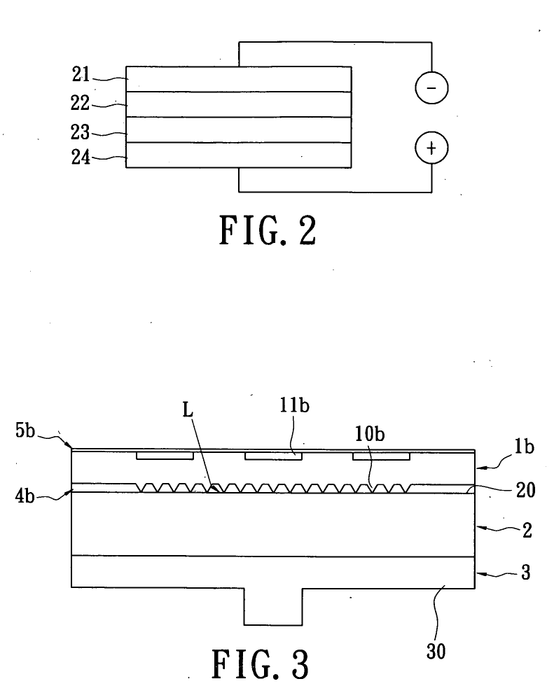

Referring to FIGS. 1 and 2, FIG. 1 shows a side, schematic view of a key module with energy storage function according to the first embodiment of the present invention, and FIG. 2 shows a side, schematic view of a sun cell of the present invention. The first embodiment of the present invention provides a key module with energy storage function, including a transparent key unit 1a, a sun cell 2, and an elastic unit 3.

The transparent key unit la is composed of a plurality of key bodies 10 (FIG. 1 shows only one of the key bodies 10). In addition, the transparent key unit la has a plurality of transparent microstructures 10a disposed on a top surface of the transparent key unit 1a, and the transparent microstructures 10a are reverse prismatic structures. Furthermore, the transparent key unit 1a has a plurality of opaque background showing bodies 11a disposed on a bottom surface of the transparent key unit 1a, and the opaque background showing bodies 11a can be opaque patterns, opaque symbols, opaque words or opaque numerals.

Moreover, the sun cell 2 is disposed under a bottom side of the transparent key unit 1a, and the sun cell 2 has a light-receiving face 20 facing the transparent key unit 1a. Referring to FIG. 2, the sun cell 2 is composed of an upper electrode 21, a n-type semiconductor 22, a p-type semiconductor 23 and a lower electrode 24. The p-type semiconductor 23 is disposed on the lower electrode 24, the n-type semiconductor 22 is disposed on the p-type semiconductor 23, and the upper electrode 24 is disposed on the n-type semiconductor 22.

Furthermore, the operation principle of the sun cell 2 is: when light source is shone on the n-type semiconductor 22 and the p-type semiconductor 23, the holes with positive electricity of the n-type semiconductor 22 move toward the p-type semiconductor 23 and the electrons with negative electricity of the p-type semiconductor 23 move toward the n-type semiconductor 22. Therefore, when light source is shone on the sun cell 2, the luminous energy is transformed into the electric energy in order to supply power.

Moreover, the elastic unit 3 is composed of a plurality of elastic bodies 30 corresponding to the key bodies 10 (FIG. 1 shows only one of the elastic bodies 30). The elastic unit 3 is disposed under a bottom side of the sun cell 2, and the elastic unit 3 can be made of a rubber material.

In addition, the first embodiment of the present invention further includes an adhesive layer 4a an anti-IR (infrared) coating layer unit 5a. The adhesive layer 4a is disposed between the transparent key unit 1a and the sun cell 2. The anti-IR coating layer unit 5a is disposed on a top surface of the sun cell 2, and the anti-IR coating layer unit 5a can be an anti-IR coating layer or can be composed of a plurality of anti-IR coating layers.

Hence, when external light sources L are shone on the transparent key unit 1a, the transparent microstructures 10a of the transparent key unit 1a guide and transmit the external light sources L onto the light-receiving face 20 of the sun cell 2 in order to increase light source on the light-receiving face 20.

FIG. 3 shows a side, schematic view of a key module with energy storage function according to the second embodiment of the present invention. The difference between the second embodiment and the first embodiment is that: a transparent key unit 1b has a plurality of transparent microstructures 10b, and the transparent microstructures 10b are disposed on a bottom surface of the transparent key unit 1b. Moreover, the transparent key unit 1b has a plurality of opaque background showing bodies 11b disposed on a top surface of the transparent key unit 1b, and the opaque background showing bodies 11b can be opaque patterns, opaque symbols, opaque words or opaque numerals.

Furthermore, the second embodiment of the present invention further includes an adhesive layer 4b an anti-IR coating layer unit 5b. The adhesive layer 4b is disposed between the transparent key unit 1b and the sun cell 2. The anti-IR coating layer unit 5b is disposed on a top surface of the transparent key unit 1b, and the anti-IR coating layer unit 5b can be an anti-IR coating layer or can be composed of a plurality of anti-IR coating layers.

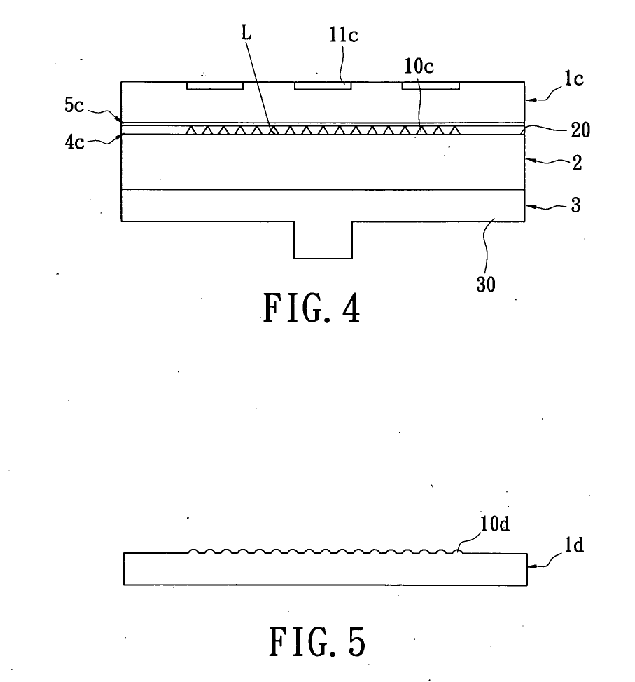

FIG. 4 shows a side, schematic view of a key module with energy storage function according to the third embodiment of the present invention. The third embodiment of the present invention provides a key module with energy storage function, including a transparent key unit 1c, a sun cell 2, a plurality of transparent microstructures 10c, and an elastic unit 3.

The difference between the third embodiment and the first and second embodiments is that: a transparent microstructures 10c are disposed between the transparent key unit 1c and the sun cell 2. Moreover, the transparent key unit 1c has a plurality of opaque background showing bodies 11c disposed on a top surface of the transparent key unit 1c (or a bottom surface of the transparent key unit 1c), and the opaque background showing bodies 11c can be opaque patterns, opaque symbols, opaque words or opaque numerals. In the fourth embodiment, transparent microstructures 10c are disposed on a top surface of the light-receiving face 20 of the sun cell 2, and the opaque background showing bodies 11c are disposed on a top surface of the transparent key unit 1c.

Furthermore, the third embodiment of the present invention further includes an adhesive layer 4c an anti-IR coating layer unit 5c. The adhesive layer 4c is disposed between the transparent key unit 1c and the sun cell 2. The anti-IR coating layer unit 5c is disposed on a bottom surface of the transparent key unit 1c, and the anti-IR coating layer unit 5c can be an anti-IR coating layer or can be composed of a plurality of anti-IR coating layers.

Hence, when external light sources L are shone on the transparent key unit 1c, the transparent microstructures 10c guide and transmit the external light sources L onto the light-receiving face 20 of the sun cell 2 in order to increase light source on the light-receiving face 20.

Moreover, the transparent microstructures (10a, 10b, 10c) can be changed into a plurality of half round structures. For example, FIG. 5 shows a side, schematic view of another transparent microstructures of the present invention. A transparent key unit 1d has a plurality of transparent microstructures 10d, and the transparent microstructures 10d are half round structures. In other words, the shapes of the transparent microstructures (10a, 10b, 10c, 10d) of the different embodiments do not limit the present invention. Any shapes of the transparent microstructures are protected in the present invention.

In conclusion, the sun cell and the transparent microstructures are mated with each other in order to increase light source received by the sun cell, and the power supply of sun cell can be increased. Hence, the present invention has a background showing function, a pressing function, and a power-storing function.

Hence, the key module with energy storage function of the present invention has some advantages, as follows:

1. The background showing function (such as shown words), the pressing function and the power-storing function are all in the same key module.

2. The sun cell is applied to the key module in order to increase the usage time of an electronic product using the key module.

3. The transparent microstructures are used to increase the light-receiving efficiency of the sun cell.

4. The traditional rechargeable battery is replaced with the sun cell in order to take the environment and the convenience into account.

5. The present invention takes the environment and the convenience into account without using battery charger.

6. The anti-IR coating layer is used to decrease the sunshine temperature of the key module in the daytime and protect the relevant electronic components of the key module.

7. The adhesive layer is used to fix the transparent key unit on the sun cell in order to decrease reflection or total reflection of the external light sources and increase the light-receiving efficiency of the sun cell.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A key module with energy storage function, comprising:
a transparent key unit having a plurality of transparent microstructures;
a sun cell disposed under a bottom side of the transparent key unit, wherein the sun cell has a light-receiving face facing the transparent key unit; and
an elastic unit disposed under a bottom side of the sun cell;
wherein the transparent microstructures of the transparent key unit guide and transmit external light sources onto the light-receiving face of the sun cell in order to increase light source on the light-receiving face.

2. The key-module as claimed in claim 1, wherein the transparent key unit is composed of a plurality of key bodies, and the elastic unit is composed of a plurality of elastic bodies corresponding to the key bodies.

3. The key module as claimed in claim 1, wherein the transparent key unit has a plurality of opaque patterns, opaque symbols, opaque words or opaque numerals formed on a top surface thereof.

4. The key module as claimed in claim 1, wherein the transparent key unit has a plurality of opaque patterns, opaque symbols, opaque words or opaque numerals formed on a bottom surface thereof.

5. The key module as claimed in claim 1, wherein the transparent microstructures are disposed on a top surface or a bottom surface of the transparent key unit.

6. The key module as claimed in claim 1, wherein the transparent microstructures are prismatic structures or half round structures.

7. The key module as claimed in claim 1, wherein the sun cell is composed of an upper electrode, a n-type semiconductor, a p-type semiconductor and a lower electrode, and the p-type semiconductor is disposed on the lower electrode, the n-type semiconductor is disposed on the p-type semiconductor, the upper electrode is disposed on the n-type semiconductor.

8. The key module as claimed in claim 1, further comprising an adhesive layer disposed between the transparent key unit and the sun cell, wherein the elastic unit is a rubber material.

9. The key module as claimed in claim 1, further comprising an anti-IR (infrared) coating layer unit selectively disposed on a top surface or a bottom surface of the transparent key unit or on a top surface of the sun cell.

10. The key module as claimed in claim 9, wherein the anti-IR coating layer unit is an anti-IR coating layer or is composed of a plurality of anti-IR coating layers.

11. A key module with energy storage function, comprising:
a transparent key unit;
a sun cell disposed under a bottom side of the transparent key unit, wherein the sun cell has a light-receiving face facing the transparent key unit;
a plurality of transparent microstructures disposed between the transparent key unit and the sun cell; and
an elastic unit disposed under a bottom side of the sun cell;
wherein the transparent microstructures guide and transmit external light sources onto the light-receiving face of the sun cell in order to increase light source on the light-receiving face.

12. The key module as claimed in claim 11, wherein the transparent key unit is composed of a plurality of key bodies, and the elastic unit is composed of a plurality of elastic bodies corresponding to the key bodies.

13. The key module as claimed in claim 11, wherein the transparent key unit has a plurality of opaque patterns, opaque symbols, opaque words or opaque numerals formed on a top surface thereof.

14. The key module as claimed in claim 11, wherein the transparent key unit has a plurality of opaque patterns, opaque symbols, opaque words or opaque numerals formed on a bottom surface thereof.

15. The key module as claimed in claim 11, wherein the transparent microstructures are prismatic structures or half round structures.

16. The key module as claimed in claim 11, wherein the sun cell is composed of an upper electrode, a n-type semiconductor, a p-type semiconductor and a lower electrode, and the p-type semiconductor is disposed on the lower electrode, the n-type semiconductor is disposed on the p-type semiconductor, the upper electrode is disposed on the n-type semiconductor.

17. The key module as claimed in claim 11, wherein the transparent microstructures are disposed on a top surface of the light-receiving face of the sun cell.

18. The key module as claimed in claim 11, further comprising an adhesive layer disposed between the transparent key unit and the sun cell, wherein the elastic unit is a rubber material.

19. The key module as claimed in claim 11, further comprising an anti-IR (infrared) coating layer unit selectively disposed on a top surface or a bottom surface of the transparent key unit or on a top surface of the sun cell.

20. The key module as claimed in claim 19, wherein the anti-IR coating layer unit is an anti-IR coating layer or is composed of a plurality of anti-IR coating layers.
